(19) United States
(12) Patent Application Publication
(10) Pub. No.: US 2026/0338862 A1
(43) Pub. Date: Oct. 29, 2026

(54) Application-Specific Integrated Circuit and Methods of Manufacturing Thereof

(71) Applicant: Sandisk Technologies, Inc., Milpitas, CA (US)

(72) Inventors: John Randall, Fremont, CA (US); Nathan DeNeui, Irvine, CA (US); Brian Huang, San Jose, CA (US); Atif Hussain, Denver, CO (US); Tien-chien Kuo, Sunnyvale, CA (US)

(73) Assignee: Sandisk Technologies, Inc., Milpitas, CA (US)

(21) Appl. No.: 19/188,798

(22) Filed: Apr. 24, 2025

(51) Int. Cl. G01R 31/3185; G01R 31/317

(52) U.S. Cl. CPC G01R 31/318597; G01R 31/31704; G01R 31/31725

(57) ABSTRACT

A method to manufacture an application-specific integrated circuit includes fabricating the application-specific integrated circuit with a processor, a one-time programmable memory module, and a hardware interface. The hardware interface is configured to permit writing instructions to the one-time programmable memory module. Advantageously, by utilizing a one-time programmable (OTP) memory module, the ASIC can enable code changes without requiring an iteration or spin of the fabrication process.

### BACKGROUND

The present disclosure generally relates to application-specific integrated circuits and methods of manufacturing thereof, and more particularly to application-specific integrated circuits and methods of manufacturing thereof that minimize development time and cost.

In contrast to a general-purpose processor or integrated circuit, an application-specific integrated circuit (ASIC) is an integrated circuit developed for a specific use. For example, an ASIC can be designed or utilized for various applications, such as a controller for a solid-state storage device.

ASICs can include built in processors, memory blocks or modules such as read-only memory (ROM), random access memory (RAM), electrically erasable programmable read-only memory (EEPROM), flash memory, and other modules or blocks. ASICs can be designed using a hardware description language (HDL), such as Verilog or VHDL to describe the functionality of ASICs.

The processors within an ASIC require code to boot. In certain conventional applications, the boot code is built into the ASIC hardware and fabricated as part of the ASIC fabrication process. However, if the boot code built into the ASIC hardware needs to be revised after fabrication, the ASIC must be redesigned to revise the boot code, which is time and resource intensive. Therefore, there is a need to provide ASICs and methods of manufacturing thereof that minimize the time and resources required to revise boot code used with ASIC hardware.

### SUMMARY

In one embodiment a method to manufacture an application-specific integrated circuit includes fabricating the application-specific integrated circuit, the application-specific integrated circuit including: a processor; a one-time programmable memory module; and a hardware interface configured to permit writing instructions to the one-time programmable memory module.

In some embodiments, the one-time programmable memory module can contain executable instructions which when executed by the processor cause the processor to: boot the application-specific integrated circuit. In some embodiments, the method can further include designing the application-specific integrated circuit before fabricating the application-specific integrated circuit; and writing instructions to the one-time programmable memory module after fabricating the application-specific integrated circuit. In some embodiments, the method can further include verifying a design of the application-specific integrated circuit before fabricating the application-specific integrated circuit; and writing instructions to the one-time programmable memory module after verifying the design of the application-specific integrated circuit. In some embodiments, the method can further include finalizing a design of the application-specific integrated circuit before fabricating the application-specific integrated circuit; and writing instructions to the one-time programmable memory module after finalizing the design of the application-specific integrated circuit. In some embodiments, the hardware interface can include a Joint Test Action Group (JTAG) interface. In some embodiments, the method can further include writing instructions to the one-time programmable memory module via the hardware interface. In some embodiments, writing instructions to the one-time programmable memory module can include writing instructions to enable clock signals. In some embodiments, writing instructions to the one-time programmable memory module can include writing instructions to enable a non-volatile memory interface. In some embodiments, writing instructions to the one-time programmable memory module can include writing instructions to read a boot page from a non-volatile memory module.

In one embodiment a method to program an application-specific integrated circuit includes accessing a one-time programmable memory module of the application-specific integrated circuit via a hardware interface of the application-specific integrated circuit; and writing instructions to the one-time programmable memory module via the hardware interface.

In some embodiments, writing instructions to the one-time programmable memory module can include writing instructions to enable clock signals. In some embodiments, writing instructions to the one-time programmable memory module can include writing instructions to enable a non-volatile memory interface. In some embodiments, writing instructions to the one-time programmable memory module can include writing instructions to read a boot page from a non-volatile memory module. In some embodiments, the method further includes overwriting instructions contained on the one-time programmable memory module via the hardware interface.

In one embodiment an application-specific integrated circuit includes a processor; a hardware interface; and a one-time programmable memory module containing one-time programmable executable instructions which when executed by the processor to cause the processor to perform a method, the method including: booting the application-specific integrated circuit.

In some embodiments, the hardware interface includes a Joint Test Action Group (JTAG) interface. In some embodiments, the method further includes enabling clock signals. In some embodiments, the method further includes enabling a non-volatile memory interface. In some embodiments, the method further includes reading a boot page from a non-volatile memory module via the non-volatile memory interface.

### BRIEF DESCRIPTION OF THE DRAWINGS

The foregoing summary, as well as the following detailed description, will be better understood when read in conjunction with the appended drawings. For the purpose of illustrating the present disclosure, there are shown in the drawings embodiments, which are presently preferred, wherein like reference numerals indicate like elements throughout. It should be noted, however, that aspects of the present disclosure can be embodied in different forms and thus should not be construed as being limited to the illustrated embodiments set forth herein. The elements illustrated in the accompanying drawings are not necessarily drawn to scale, but rather, may have been exaggerated to highlight the important features of the subject matter therein. Furthermore, the drawings may have been simplified by omitting elements that are not necessarily needed for the understanding of the disclosed embodiments.

In the drawings:

FIG. 1 is a block diagram of a prior art application-specific integrated circuit (ASIC);

FIG. 2 is a flowchart diagram illustrating a prior art method of manufacturing the ASIC of FIG. 1;

FIG. 3 is a block diagram of an ASIC in accordance with an embodiment of the present disclosure; and

FIG. 4 is a flowchart diagram illustrating a method of manufacturing the ASIC of FIG. 3 in accordance with an embodiment of the present disclosure.

### DETAILED DESCRIPTION

The present subject matter will now be described more fully hereinafter with reference to the accompanying Figures, in which representative embodiments are shown. The present subject matter can, however, be embodied in different forms and should not be construed as limited to the embodiments set forth herein. Rather, these embodiments are provided to describe and enable one of skill in the art.

In one embodiment, the systems and methods discussed herein include one or more computers or computing devices (e.g., the controllers referenced herein) having one or more processors and memory (e.g., one or more nonvolatile storage devices). In some embodiments, memory or computer readable storage medium(s) of memory store programs, modules and data structures, or a subset thereof, for a processor to control and run the various systems and methods disclosed herein. In one embodiment, a non-transitory computer readable storage medium having stored thereon computer-executable instructions which, when executed by a processor, performs one or more of any combination of the methods or steps disclosed herein. Numerous details are described herein in order to provide a thorough understanding of the example embodiments illustrated in the accompanying drawings. However, some embodiments may be practiced without any of the specific details, and the scope of the claims is only limited by those features and aspects specifically recited in the claims. Furthermore, well-known methods, components, and circuits have not be described in exhaustive detail so as not to unnecessarily obscure pertinent aspects of the embodiments described herein.

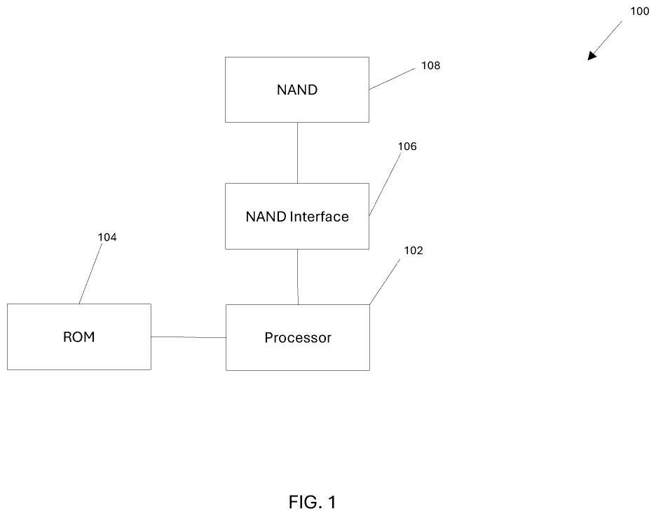

FIG. 1 is a block diagram of a prior art application-specific integrated circuit (ASIC) 100. With reference to FIG. 1, in some applications, a prior art ASIC 100 can be used as a controller to access non-volatile flash memory, such as NAND memory 108. In the depicted example, the processor 102 may access, control, or otherwise interact with the NAND memory 108 through an interface 106.

In some applications, the ROM 104 can store boot code that is required to boot the processor 102. For example, the ROM 104 can include instructions for execution by the processor 102 to enable clock signals of the ASIC 100, enable a Peripheral Component Interconnect Express (PCIe) interface, enable a Joint Test Action Group (JTAG) interface, enable a NAND interface 106, and/or read a boot page from the NAND memory 108 via the NAND interface 106. In some applications, stored boot instructions in the ROM 104 can require up to approximately 5,000 lines of code.

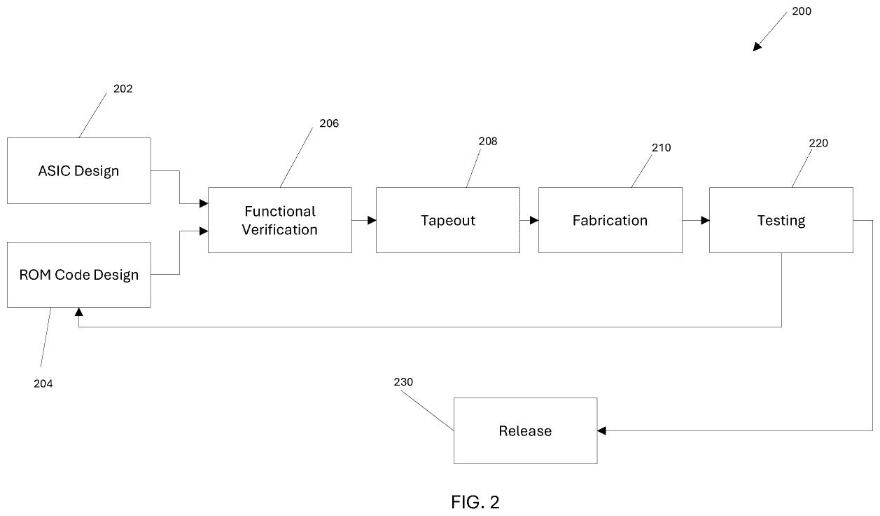

FIG. 2 is a flowchart diagram illustrating a prior art method 200 of manufacturing the ASIC 100 of FIG. 1. In some applications, the boot code or instructions contained in the ROM 104 is fabricated as part of the ASIC fabrication process 200. As described herein, while the boot code or instructions of the ROM 104 may be simulated during functional verification 206 prior to tapeout 208 and fabrication 210 of the ASIC 100, since conventional ASICs 100 cannot be reprogrammed, any undetected errors or issues during functional verification 206 that are later detected during testing 220 of the ASIC 100 will require a fix or revision and another iteration or “spin” of the fabrication process 200 prior to release 230 of the ASIC 100. In some applications, the fabrication process 200 of certain ASICs 100 may go through a series of iterations or spins, in which errors are detected and fixed after testing the first article. Various factors can cause a spin, including, but not limited to a taped-out design failing final checks at the foundry due to problems in manufacturing the ASIC design, or the first article failing functionality tests. Since the fabrication process 200 for the ASIC 100 can be long and complex, each iteration or spin of the fabrication process can be time and resource intensive.

In some applications, the initial step of the fabrication process 200 is the ASIC design phase 202. During the ASIC design phase 202, design engineers can perform a requirements analysis and identify required functions for the ASIC 100. The design team can create a register-transfer level (RTL) design of the ASIC 100 using a hardware description language.

Simultaneously, ROM code or instructions contained in the ROM 104 are designed in the ROM code design phase 204. Since the ROM code is fabricated as part of the ASIC fabrication process 200, the ROM code must be designed in parallel to the ASIC design phase 202 and completed prior to functional verification 206, tapeout 208, and fabrication 210. In some applications, since the ROM code may include numerous and/or complex instructions (e.g. in excess of approximately 5,000 lines of code) to the processor 102, development of the ROM code may introduce complexity, errors, or other issues into the ASIC and may delay functional verification 206, tapeout 208, and fabrication 210.

After the ASIC and ROM code design is complete, the ASIC design and ROM code design proceed to functional verification 206. During functional verification 206, the suitability for purpose of the ASIC design and ROM code design is verified through simulation via test benches, emulation, and/or software modeling. In some embodiments, multiple verification techniques are utilized.

After functional verification 206, the ASIC design is finalized in the tapeout 208. In some applications, finalizing the ASIC design can include logic synthesis to transform the RTL into pre-characterized standard cells or logic gates performing specific functions. Further, finalizing can include placing the standard cells on an integrated circuit die. In some embodiments, the placement of the standard cells can be optimized. Additionally, finalizing can include routing electrical connections between the standard cells. During tapeout 208 the final design or graphic for the photomask of the circuit is sent or otherwise transmitted to the fabrication facility. In some applications, the fabrication facility may make modifications to improve manufacturability of the layout. In some applications, the tapeout 208 can take approximately two or more months.

After tapeout 208, the ASIC 100 can be fabricated during fabrication 210. In some applications, the fabrication facility may perform final checks to compute parasitic resistances and capacitances, static timing analysis, design rule checking, and power analysis. In some applications, a taped out design may fail final checks at the fabrication facility due to problems with manufacturing the provided design, requiring an iteration of the fabrication process 200 to revise the ASIC design. In some applications, fabrication 210 can take approximately three or more months.

After receiving the manufactured ASICs 100, the ASICs 100 can be tested in the testing phase 220. During testing, the functionality of the ASIC 100, including the ROM code, is tested and verified. In some applications, the testing phase 220 can take approximately 2 months. If the ASIC 100 fails functionality tests, an iteration of the fabrication process 200 is required to revise the ASIC design in the ASIC design phase 202. Further, if an error, issue, or new requirement is detected or discovered during testing of the ROM code, an iteration of the fabrication process 200 is required to revise the ROM code design in the ROM code design phase 204. In certain applications, multiple iterations or spins of the fabrication process 200 may be required to fully address errors, issues, or requirements with respect to ROM code of the ASIC 100. After the ASIC 100 passes functionality testing, the ASIC design can be released for production in the release phase 230.

Certain conventional ASIC designs have utilized external EPROM in an attempt to facilitate boot code revisions without iterating the fabrication process 200. However, approaches that utilize external EPROM are costly and require significant physical space and are therefore undesirable.

In contrast to certain conventional ASIC designs, such as prior art ASIC 100, embodiments of the present disclosure utilize a one-time programmable (OTP) memory module to eliminate the ROM or minimize code contained in the ROM, and enable code changes without requiring an iteration or spin of conventional fabrication processes, such as prior art fabrication process 200. Therefore, in some embodiments of the present disclosure, the ASIC may not include a ROM for boot operations, eliminating the risk of ROM failure after fabrication. Since certain embodiments of the present disclosure may minimize the code contained in the ROM, embodiments of the present disclosure can allow for a converged code base for ASICs that utilize an OTP memory module. Advantageously, a converged code base can minimize engineering efforts to design ROM code and provide a “known-good” implementation for the ROM code, minimizing verification of the image.

Further, embodiments of the present disclosure can allow a significant reduction in the non-recurring engineering (NRE) time and resources required to fabricate an ASIC. Additionally, embodiments of the present disclosure can allow for more time to validate and change code, to allow issues to be addressed, requested changes, and new features to be added late in the development cycle without iterating the fabrication process.

In some embodiments of the present disclosure, the OTP memory module can include more storage space than certain conventional ROM modules, which may allow for future updates to the OTP, enabling feature enhancements and fixes beyond initial programming. Further, in some embodiments of the present disclosure, the OTP memory module can allow a user to select between multiple images stored on the OTP memory module.

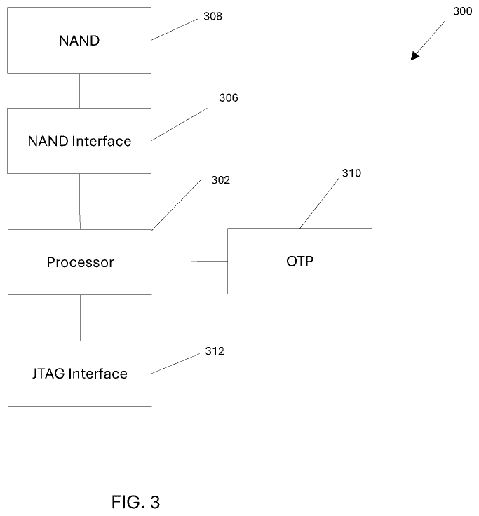

FIG. 3 is a block diagram of an ASIC 300 in accordance with an embodiment of the present disclosure. With reference to FIG. 3, the ASIC 300 may be used for any suitable purpose, including, but not limited to a controller to access non-volatile flash memory, such as NAND 308. In the illustrated example, the processor 302 may be configured to access, control, or otherwise interact with the NAND memory 308.

In contrast to prior art ASIC 100 and ROM 104, the ASIC 300 can be configured to either to (i) permit programming of an OTP memory module 310 and/or (ii) read boot code or instructions from the OTP memory module 310 to boot the processor 302. In some embodiments, a Joint Test Action Group (JTAG) interface 312 can allow programming of and/or or access to the OTP memory module 310.

Optionally, in some embodiments, the ASIC 300 can include a ROM that may be configured to store a reduced or minimized boot code or instruction set to (i) facilitate programming the OTP memory module 310 and/or (ii) read boot code or instructions from the OTP memory module 310 to boot the processor 302. Further, the reduced instruction set of the ROM may include instructions for execution by the processor 302 to allow reading from a one-time programmable (OTP) module 310, which can contain further boot code or instructions for execution by the processor 302. In some embodiments, the reduced instruction set of the ROM may be smaller than the stored boot instructions of certain conventional ASICs 100 and ROMs 104. For example, the reduced instruction set of the ROM 304 may be approximately 1,000 lines of code.

In the illustrated example, the OTP memory module 310 may be configured to store boot code that is required to boot the processor 302. In contrast to prior art ROM 104, the OTP memory module 310 may be programmed after the ASIC 300 is fabricated without modifying the design of the ASIC 300. In some embodiments, the OTP memory module 310 may be programmed via the JTAG interface 312. In some embodiments, the OTP memory module 310 may be programmed to include instructions for execution by the processor 302 to enable clock signals of the ASIC 300, enable a NAND interface 306, and/or read a boot page from the NAND memory 308. In some applications, stored boot instructions in the OTP memory module 310 may be larger than the reduced instruction set stored in ROM (if present). In some embodiments, the instructions stored or programmed into the OTP memory module 310 may include up to approximately 5,000 lines of code. In some embodiments, the OTP memory module 310 may have a storage capacity sufficient to contain multiple images and/or instruction sets (e.g., lines of code) to allow for testing of different selectable boot modes for the ASIC 300. In some embodiments, new or additional code, including feature enhancements or fixes, may be added via updates to the OTP memory module 310 at a later time, for example, after the ASIC 300 is deployed or installed.

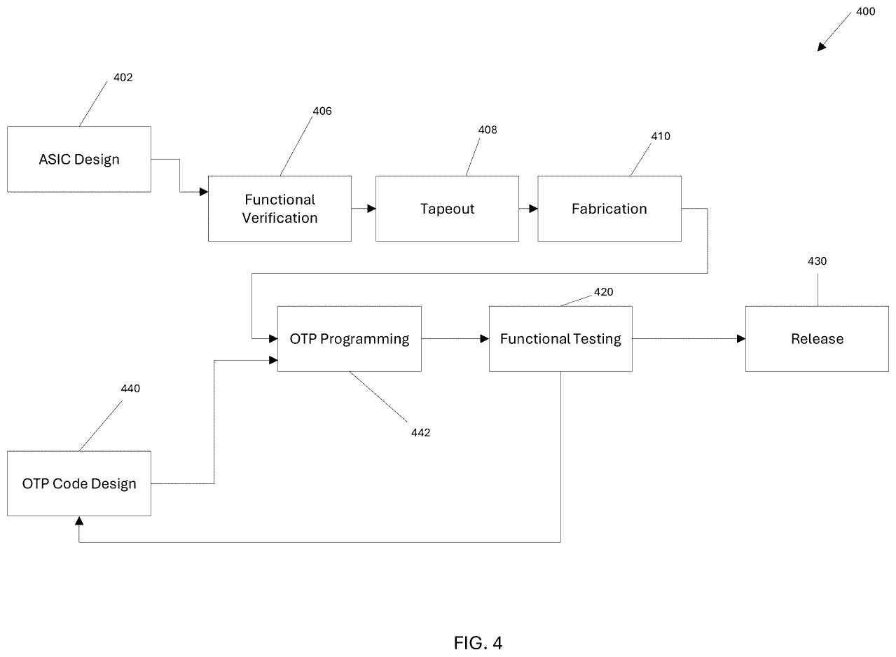

FIG. 4 is a flowchart diagram illustrating a method 400 of manufacturing the ASIC 300 of FIG. 3 in accordance with an embodiment of the present disclosure. As discussed herein, boot code or an instruction set can be programmed into the OTP memory module 310 after the fabrication process, streamlining testing and any potential revisions of the instruction set by allowing for any revisions to the instructions stored in the OTP memory module 310 to be implemented in the same or another ASIC 300 article without performing another iteration or “spin” of the fabrication process 400 prior to release 430 of the ASIC 300. Advantageously, by reducing the need for additional iterations or “spins” of the fabrication process, the ASIC fabrication process 400 can less time and resource intensive.

In the depicted example, the initial step of the fabrication process 400 is the ASIC design phase 402. During the ASIC design phase 402, design engineers may perform a requirements analysis and identify required functions for the ASIC 300. The design team may create a register-transfer level (RTL) design of the ASIC 300 using a hardware description language.

As described herein, ASIC 300 may not require a ROM to contain boot code or instructions. Optionally, if the ASIC 300 includes a ROM, the reduced or minimized ROM code or instructions contained in the ROM are designed in the ROM code design phase, in parallel with the ASIC design phase 402. Advantageously, due to the reduced size and/or minimized complexity of the ROM code contained in the ROM, the potential for the ROM code introducing errors or issues during operation of the ASIC, as well as the duration of the ROM code design phase can be minimized. If the ASIC 300 includes a ROM, the use of minimized code within the ROM may allow for the use of a converged code base for ASICs that may utilized an OTP memory module. Advantageously, the use of a converged code base may minimize engineering efforts in the ROM code design phase.

In some embodiments, the fabrication process 400 includes functional verification 406. For example, after the ASIC design is complete, the ASIC design proceed to functional verification 406. During functional verification 406, the suitability for purpose of the ASIC design may be verified through simulation via test benches, emulation, and/or software modeling. In some embodiments, multiple verification techniques are utilized. If the ASIC 300 includes ROM, the minimized code within the ROM can streamline verification. Further, in some applications, the use of a converged code base can provide a “known-good” implementation for the ROM code further minimizing verification of the image.

After functional verification 406, the ASIC design may be finalized in the tapeout 408. In some applications, finalizing the ASIC design during tapeout 408 may include logic synthesis to transform the RTL into pre-characterized standard cells or logic gates performing specific functions. Further, finalizing the tapeout 408 may include placing the standard cells on an integrated circuit die. Finalizing the tapeout 408 may include routing electrical connections between the standard cells. During tapeout 408 the final design or graphic for the photomask of the circuit may be sent or otherwise transmitted to the fabrication facility. In some applications, the fabrication facility may make modifications to improve manufacturability of the layout.

The method 400 may include the step 410 of fabricating the ASIC 300. In some applications, the step 410 includes, at for example a fabrication facility, performing final checks to compute parasitic resistances and capacitances, static timing analysis, design rule checking, and power analysis. In some embodiments, following step 410 an ASIC 300 may be produced for testing and/or further production processing.

In some embodiments, after fabrication of the ASICs 300, the functionality of the ASIC 300 and the code contained in the OTP memory module 310 can be tested during a testing phase. As described herein, revisions, fixed, updates, or other changes to the code contained in the OTP memory module 310 can be implemented in the same or another ASIC 300 article without performing another iteration or “spin” of the fabrication process 400 prior to release 430 of the ASIC 300.

In some embodiments, code or instructions to boot the processor 302 can be designed in the OTP code design phase 440. Advantageously, the code or instruction set can be developed or designed independently or simultaneously with other steps of the fabrication process 400. In some embodiments, the OTP code is designed after the fabrication 410 of the ASIC 300.

In some embodiments, the OTP memory module 310 can be programmed in the OTP programming phase 442. In some embodiments, the OTP programming phase 442 can coincide with the wafer test after fabrication 410. Advantageously, the use of the OTP memory module 310 enables flexibility with respect to the OTP programming phase 442. In some embodiments, the OTP programming phase 442 can occur during an assembly test of the ASIC 300 or during a validation phase. In some applications, the OTP programming phase 442 can be moved earlier or later relative to the development and validation of the ASIC 300 based on the stability and validation of the OTP code. Further, in some applications, a later OTP programming phase 442 may be desired to implement customer specific features within the OTP memory module 310.

As described herein, the JTAG interface 312 can allow access to the OTP memory module 310. In some embodiments, the ASIC 300 can stop code until the OTP memory module 310 is programmed. After the OTP memory module 310 is accessed via the JTAG interface 312, the code or instruction set from the OTP code design phase 440 can be written to the OTP memory module 310. In some embodiments, multiple instruction sets or images can be programmed into the OTP memory module 310 to allow for testing or selectable boot modes for the ASIC 300. In some applications, the code or instruction set from the OTP code design phase 440 can be temporarily written to RAM for validation before committing the code to the OTP memory module 310.

During the functional testing phase 420, the functionality of the ASIC 300, including the OTP code, is tested and verified. Advantageously, due to the elimination of the ROM or alternatively the reduced complexity of the ROM code stored in ROM, the likelihood of an error, issue, or new requirement that requires an iteration of the fabrication process 400 is reduced.

If an error, issue, or new requirement is detected during the testing of the OTP code, the OTP code can return to and be revised in the OTP code design phase 440. After the OTP code is revised, the revised OTP code can be programmed into another ASIC 300 article in the OTP programming phase 442 for additional testing without performing another iteration or “spin” of the fabrication process 400. In some embodiments, the revised OTP code can be written into a previously written OTP memory module 310 by erasing (i.e. “zeroing out”) or otherwise disabling the previous code and writing to another portion of the OTP memory module 310. Advantageously, the rapid revision process enabled by the use of the OTP memory module 310 allows for more time for validation, changes, and new features late in the development cycle without iterating the fabrication process. After the ASIC 300 passes functionality testing, the ASIC design can be released for production in the release phase 430.

It will be appreciated by those skilled in the art that changes could be made to the exemplary embodiments shown and described above without departing from the broad inventive concepts thereof. It is understood, therefore, that this invention is not limited to the exemplary embodiments shown and described, but it is intended to cover modifications within the spirit and scope of the present invention as defined by the claims. For example, specific features of the exemplary embodiments may or may not be part of the claimed invention and various features of the disclosed embodiments may be combined. The words “right”, “left”, “lower” and “upper” designate directions in the drawings to which reference is made. Unless specifically set forth herein, the terms “a”, “an” and “the” are not limited to one element but instead should be read as meaning “at least one”. As used herein, the term “about” may refer to +/−10% of the value referenced. For example, “about 9” is understood to encompass 8.1 and 9.9.

It is to be understood that at least some of the figures and descriptions of the invention have been simplified to focus on elements that are relevant for a clear understanding of the invention, while eliminating, for purposes of clarity, other elements that those of ordinary skill in the art will appreciate may also comprise a portion of the invention. However, because such elements are well known in the art, and because they do not necessarily facilitate a better understanding of the invention, a description of such elements is not provided herein.

Further, to the extent that the methods of the present invention do not rely on the particular order of steps set forth herein, the particular order of the steps should not be construed as limitation on the claims. Any claims directed to the methods of the present invention should not be limited to the performance of their steps in the order written, and one skilled in the art can readily appreciate that the steps may be varied and still remain within the spirit and scope of the present invention.

What is claimed is:

1. A method of manufacturing an application-specific integrated circuit, the method comprising:
fabricating the application-specific integrated circuit, the application-specific integrated circuit comprising:
a processor;
a one-time programmable memory module; and
a hardware interface configured to permit writing instructions to the one-time programmable memory module.

2. The method of claim 1, wherein the one-time programmable memory module contains executable instructions which when executed by the processor cause the processor to boot the application-specific integrated circuit.

3. The method of claim 1, further comprising:
designing the application-specific integrated circuit before fabricating the application-specific integrated circuit; and
writing instructions to the one-time programmable memory module after fabricating the application-specific integrated circuit.

4. The method of claim 1, further comprising:
verifying a design of the application-specific integrated circuit before fabricating the application-specific integrated circuit; and
writing instructions to the one-time programmable memory module after verifying the design of the application-specific integrated circuit.

5. The method of claim 1, further comprising:
finalizing a design of the application-specific integrated circuit before fabricating the application-specific integrated circuit; and
writing instructions to the one-time programmable memory module after finalizing the design of the application-specific integrated circuit.

6. The method of claim 1, wherein the hardware interface comprises a Joint Test Action Group (JTAG) interface.

7. The method of claim 1, further comprising:
writing instructions to the one-time programmable memory module via the hardware interface.

8. The method of claim 7, wherein writing instructions to the one-time programmable memory module comprises writing instructions to enable clock signals.

9. The method of claim 7, wherein writing instructions to the one-time programmable memory module comprises writing instructions to enable a non-volatile memory interface.

10. The method of claim 9, wherein writing instructions to the one-time programmable memory module comprises writing instructions to read a boot page from a non-volatile memory module.

11. A method to program an application-specific integrated circuit, the method comprising:
accessing a one-time programmable memory module of the application-specific integrated circuit via a hardware interface of the application-specific integrated circuit; and
writing instructions to the one-time programmable memory module via the hardware interface.

12. The method of claim 11, wherein writing instructions to the one-time programmable memory module comprises writing instructions to enable clock signals.

13. The method of claim 11, wherein writing instructions to the one-time programmable memory module comprises writing instructions to enable a non-volatile memory interface.

14. The method of claim 13, wherein writing instructions to the one-time programmable memory module comprises writing instructions to read a boot page from a non-volatile memory module.

15. The method of claim 11, further comprising overwriting instructions contained on the one-time programmable memory module via the hardware interface.

16. An application-specific integrated circuit comprising:
a processor;
a hardware interface; and
a one-time programmable memory module containing one-time programmable executable instructions which when executed by the processor to cause the processor to perform a method, the method comprising:
booting the application-specific integrated circuit.

17. The application-specific integrated circuit of claim 16, wherein the hardware interface comprises a Joint Test Action Group (JTAG) interface.

18. The application-specific integrated circuit of claim 16, wherein the method further comprises enabling clock signals.

19. The application-specific integrated circuit of claim 16, wherein the method further comprises enabling a non-volatile memory interface.

20. The application-specific integrated circuit of claim 19, wherein the method further comprises reading a boot page from a non-volatile memory module via the non-volatile memory interface.
